(19) United States
(12) Patent Application Publication
(10) Pub. No.: US 2026/0170206 A1
(43) Pub. Date: Jun. 18, 2026

(54) Reconfigurable 3D Chip and Integration Method Thereof

(71) Applicant: Beijing Tsingmicro Intelligent Technology Co., Ltd., Beijing (CN)

(72) Inventors: Peng Ouyang, Beijing (CN); Yi Yu, Beijing (CN)

(21) Appl. No.: 18/718,855

(22) PCT Filed: Jul. 18, 2023
(86) PCT No.: PCT/CN2023/107894

§ 371 Date: Jun. 12, 2024

(30) Foreign Application Priority Data
Jan. 31, 2023 (CN) 202310104167.1

(51) Int. Cl. G06F 30/30; H10W 90/00

(52) U.S. Cl. CPC G06F 30/30; H10W 90/00; H10W 90/732

(57) ABSTRACT

A reconfigurable 3D chip and an integration method thereof are provided. The method includes: designing the architecture of the reconfigurable 3D chip; performing semiconductor manufacturing on a reconfigurable computing logic chip of the reconfigurable 3D chip to obtain, an uncut reconfigurable logic wafer; according to the architecture of the reconfigurable 3D chip, bonding a reconfigurable logic wafer and a memory wafer together in a face-to-face manner by adopting a hybrid technology, and connecting a signal IO of the reconfigurable logic wafer and a signal IO of the memory wafer together; cutting the bonded and stacked chip to obtain an independent stacked die; and packaging the stacked die to obtain the reconfigurable 3D chip.

### CROSS-REFERENCE TO RELATED APPLICATIONS

This application is a National Stage Application under 35 USC § 371 of International Application PCT/CN2023/107894, filed Jul. 18, 2023, which claims priority to Chinese Patent Application No. 202310104167.1, filed Jan. 31, 2023, the entire contents of which are incorporated herein by reference.

### TECHNICAL FIELD

The present disclosure relates to the field of computer technology, and more particularly to a reconfigurable three-dimensional (3D) chip and an integration method thereof.

### BACKGROUND

With a continuous development of an artificial intelligence technology, a demand for a computing power of a chip is getting higher and higher. Chip designers must continue to improve the computing power to meet a growing demand for the computing power. The computing power of the chip, that is, a computing performance of the chip, is affected by many factors. Main functional components of the chip mainly include a memory, an arithmetic element, a controller, an input device and an output device. A basic working process of the chip is that original data are stored in the memory in advance or enter the memory through the input device. Under a control of a program, the controller sends the data in the memory to the arithmetic element to complete a calculation, and then writes calculated data to the memory or sends calculated data to the output device. During an entire data calculation process, the data are transferred back and forth between the memory and the arithmetic element. Therefore, an amount of data between the arithmetic element and the memory per unit time and a time spent on a transmission path of the data will directly affect a performance of the chip. An ability to transmit the data between the arithmetic element and the memory of the chip may be expressed by two parameters: a bandwidth and a latency. Modern semiconductor technology continues to develop, and a processing speed of the arithmetic element in the chip continues to increase, which has far exceeded a read and write bandwidth and the latency that the memory may provide, causing a “storage wall” problem. There are many types of memories. Currently, a large-capacity high-speed memory out of the chip is mainly a dynamic random access memory (DRAM). In a traditional architecture, there are two main forms of interconnection between the DRAM and a computing chip: a printed circuit board (PCB) board-level two-dimensional (2D) interconnection and a 2.5D interconnection of a silicon substrate. In a PCB board-level 2D interconnection form between a DRAM memory and the computing chip, a physical distance between the memory and the computing element is in a centimeter level, a load on a data signal link is also very large, and a data transmission bandwidth is very low. At the same time, due to a limitation in a number of input/output (IO) ports of the chip, an interconnection bandwidth is further limited, making it difficult to meet needs of the computing element, and resulting in a performance degradation. A 2.5D integration based on the silicon substrate interconnects a storage chiplet and a computing chiplet on one silicon substrate. Although the 2.5D integration based on the silicon substrate greatly reduces an interconnection distance as compared to a PCB board-level interconnection and reduces an interconnection distance between the memory and the computing element to a millimeter level, its essence is still a two-dimensional planar interconnection structure, improvement on a memory bandwidth is limited, and it still cannot meet computing needs. Taking as an example a 2.5D interconnection between a halt burst mode (HBM) DRAM and the computing chip, a single HBM DRAM chiplet can only provide an interface bit width of 1024 bits, and a data transmission bit width is limited.

### SUMMARY

Embodiments of the present disclosure provide a reconfigurable 3D chip and an integration method thereof.

Embodiments according to a first aspect of the present disclosure provide an integration method of a reconfigurable 3D chip, including:
designing an architecture of the reconfigurable 3D chip;
performing a semiconductor manufacturing on a reconfigurable computing logic chip of the reconfigurable 3D chip to obtain an uncut reconfigurable logic wafer;
bonding the reconfigurable logic wafer and a memory wafer together in a face-to-face manner using a hybrid technology and connecting a signal input/output (IO) of the reconfigurable logic wafer and a signal IO of the memory wafer together according to the architecture of the reconfigurable 3D chip;
cutting a bonded and stacked chip to obtain an independent stacked die; and
packaging the stacked die to obtain the reconfigurable 3D chip.

Embodiments according to a second aspect of the present disclosure provide a reconfigurable 3D chip obtained by the integration method of the reconfigurable 3D chip provided by embodiments of the first aspect described above, including:
a reconfigurable computing chiplet and a memory chiplet disposed on a top layer of the reconfigurable computing chiplet.

The memory chiplet includes a plurality of memory elements, each reconfigurable computing element of the reconfigurable computing chiplet is configured with an independent memory element, and the reconfigurable computing element and its corresponding memory element are connected in a tight coupling manner.

Embodiments according to a third aspect of the present disclosure provide a method for integrating a DRAM chiplet and a reconfigurable computing chiplet into a complete chip through a three-dimensionally stacked manner.

### BRIEF DESCRIPTION OF THE DRAWINGS

Embodiments of the present disclosure may be more completely understood by reference to the accompanying drawings below:

FIG. 1 is a schematic flowchart of an integration method of a reconfigurable 3D chip provided by an embodiment of the present disclosure;

FIG. 2 is a design flowchart of a 3D chip formed by stacking a reconfigurable computing chiplet and a memory chiplet provided by an embodiment of the present disclosure;

FIG. 3 is a schematic block diagram of a reconfigurable 3D chip provided by an embodiment of the present disclosure; and

FIG. 4 is a three-dimensional integration diagram of a memory chiplet and a reconfigurable computing chiplet provided by an embodiment of the present disclosure.

### DETAILED DESCRIPTION

Hereinafter, embodiments according to the present disclosure will be described in detail with reference to the accompanying drawings. Obviously, the described embodiments are only some embodiments of the present disclosure, rather than all embodiments of the present disclosure. It should be understood that the present disclosure is not limited to embodiments described here.

It should be noted that a relative arrangement of components and steps, numerical expressions and numerical values set forth in these embodiments are not intended to limit a scope of the present disclosure unless otherwise specifically stated.

Those skilled in the art may understand that terms such as “first” and “second” in embodiments of the present disclosure are only used to distinguish different steps, devices or modules, etc., but they do not represent any specific technical meaning, nor do they represent a necessary logical sequence between them.

It should also be understood that in embodiments of the present disclosure, “a/the plurality of” may refer to two or more than two, and “at least one” may refer to one, two, or more than two.

It should also be understood that any component, data or structure mentioned in embodiments of the present disclosure may generally be understood to mean one or more unless there is an explicit limitation or a contrary inspiration is given in the context.

In addition, the term “and/or” in the present disclosure is only an association relationship describing associated objects, indicating that three relationships may be exist. For example, A and/or B may represent three situations where: A exists alone, A and B exist simultaneously, and B exists alone. In addition, the character “/” in the present disclosure generally represents that objects associated before and after the character are in an “or” relationship.

It should also be understood that descriptions of individual embodiments of the present disclosure focus on differences between the individual embodiments, and for the same or similar parts between the individual embodiments, reference may be made to each other. For the sake of brevity, they will not be described again one by one.

At the same time, it should be understood that, for a convenience of the descriptions, dimensions of individual parts shown in the drawings are not drawn according to actual proportional relationships.

The following descriptions of at least one embodiment are merely illustrative in nature and is in no way intended to limit the present disclosure, and its applications or uses.

Techniques, methods and devices known to those of ordinary skill in the art may not be discussed in detail, but where appropriate, the techniques, the methods and the devices should be considered as a part of the specification.

It should be noted that similar reference numerals and letters express similar items in the following figures, so that once a certain item is defined in one figure, it does not require further discussion in subsequent figures.

Embodiments of the present disclosure may be applied to electronic devices such as terminal devices, computer systems, servers, etc., which may operate with numerous other general or special purpose computing system environments or configurations. Examples of well-known terminal devices, computing systems, environments and/or configurations suitable for use with the electronic devices such as the terminal devices, the computer systems, the servers, etc. include, but are not limited to: personal computer systems, server computer systems, thin clients, thick clients, handheld or laptop devices, microprocessor-based systems, set-top boxes, programmable consumer electronics, networked personal computers, small computer systems, mainframe computer systems and distributed cloud computing technology environments including any of the above systems, etc.

The electronic devices such as the terminal devices, the computer systems, the servers, etc. may be described in a general context of computer system executable instructions (such as program modules) being executed by the computer system. Generally, the program modules may include routines, programs, target programs, components, logic, data structures, etc., that perform specific tasks or implement specific abstract data types. The computer systems/servers may be implemented in the distributed cloud computing environment where tasks are performed by remote processing devices linked through a communication network. In the distributed cloud computing environment, the program modules may be located on local or remote computing system storage media including storage devices.

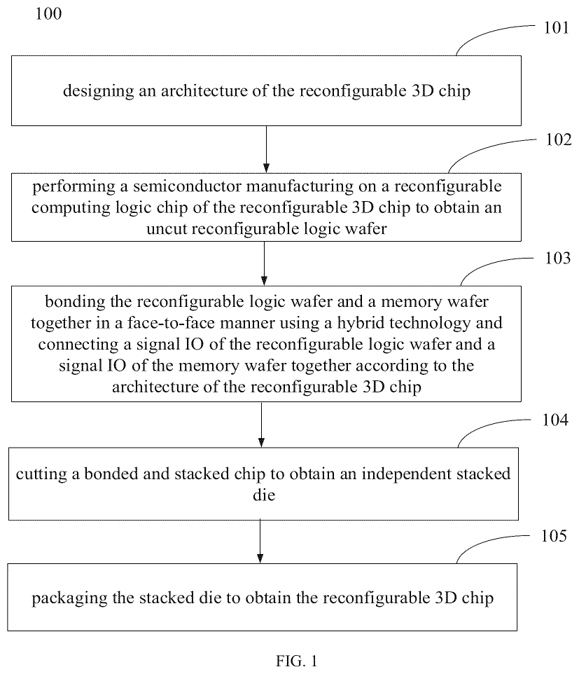

FIG. 1 is a schematic flowchart of an integration method of a reconfigurable processing chip described in embodiments of the first aspect of the present disclosure. This embodiment may be applied to an electronic device. As shown in FIG. 1, an integration method 100 for a reconfigurable 3D chip includes steps 101 to 105.

In step 101, an architecture of the reconfigurable 3D chip is designed.

In step 102, a semiconductor manufacturing is performed on a reconfigurable computing logic chip of the reconfigurable 3D chip to obtain an uncut reconfigurable logic wafer.

In step 103, the reconfigurable logic wafer and a memory wafer are bonded together in a face-to-face manner using a hybrid technology and a signal IO of the reconfigurable logic wafer and a signal IO of the memory wafer are connected together according to the architecture of the reconfigurable 3D chip.

In step 104, a bonded and stacked chip is cut to obtain an independent stacked die.

In step 105, the stacked die is packaged to obtain the reconfigurable 3D chip.

In some embodiments, the integration method of the reconfigurable 3D chip further includes:
performing a development and a verification of an RTL code of the reconfigurable 3D chip according to the architecture of the reconfigurable 3D chip to determine a chip RTL code.

In some embodiments, performing the semiconductor manufacturing on the reconfigurable computing logic chip of the reconfigurable 3D chip to obtain the uncut reconfigurable logic wafer includes:
performing a logical synthesis of the reconfigurable 3D chip according to the architecture of the reconfigurable 3D chip to obtain a gate-level netlist of the reconfigurable 3D chip;
performing a layout and a routing on the reconfigurable computing logic chip of the reconfigurable 3D chip according to the gate-level netlist to determine a GDS file of the reconfigurable computing logic chip; and
obtaining the uncut reconfigurable logic wafer through the semiconductor manufacturing of a GDS of the reconfigurable computing logic chip according to the GDS file.

In some embodiments, bonding the reconfigurable logic wafer and the memory wafer together in the face-to-face manner using the hybrid technology and connecting the signal IO of the reconfigurable logic wafer and the signal IO of the memory wafer together according to the architecture of the reconfigurable 3D chip include:
determining a hybrid bonding scheme of the reconfigurable computing logic chip according to a hybrid bonding rule of the architecture of the reconfigurable 3D chip; and
bonding the reconfigurable logic wafer and the memory wafer together in the face-to-face manner using the hybrid technology and connecting the signal IO of the reconfigurable logic wafer and the signal IO of the memory wafer together according to the hybrid bonding scheme.

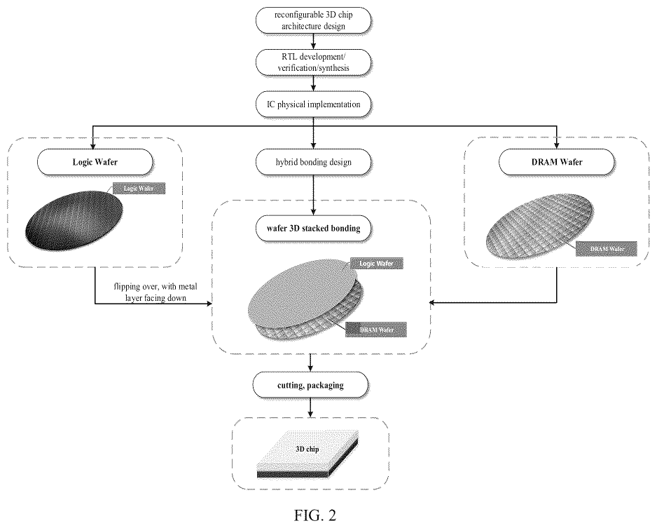

Specifically, referring to FIG. 2, which shows a design flowchart of a 3D chip formed by bonding a reconfigurable chiplet and a DRAM chiplet. The specific steps are as follows.

First, an architecture design of a reconfigurable 3D chip is performed. After a chip architecture is determined through a design space exploration, a development and a verification of an RTL code is performed to ensure a correctness of a chip RTL code.

After the verification of the RTL code is completed, a logic synthesis is performed to obtain a gate-level netlist of the chip.

Then, an integrated circuit (IC) physical implementation stage is entered, a layout and a routing on a reconfigurable computing logic chip are performed to obtain a GDS file of the reconfigurable computing logic chip and a hybrid bonding design scheme determined according to a hybrid bonding rule, ensuring a correctness of a bonding location relationship between a logic wafer and a DRAM wafer. An uncut reconfigurable logic wafer is obtained through a semiconductor manufacturing of a GDS of the reconfigurable computing logic chip.

According to a hybrid bonding scheme design, the reconfigurable logic wafer and the DRAM wafer are bonded together in a face-to-face manner using a hybrid bonding technology. The signal IO of the reconfigurable logic wafer and signal IO of the DRAM wafer are reliably connected together. Then, a bonded and stacked chip is cut and diced to obtain an independent stacked die, and the die is packaged to obtain a final reconfigurable 3D chip.

Embodiments of the present disclosure provide a method of three-dimensionally integrating a DRAM chiplet and a reconfigurable computing chiplet. The reconfigurable computing chiplet is a configurable data flow computing architecture, which is naturally well matched to an application with data flow computing characteristics. The reconfigurable computing chiplet has distributed on-chip computing resources, and combines with a three-dimensionally integrated DRAM chiplet, which may reduce a physical distance between a computing element and a storage element to a micron level, and greatly improves a memory access bandwidth and thus greatly improves a computing performance of the chip.

Therefore, the reconfigurable 3D chip in embodiments of the present disclosure adopts a reconfigurable computing architecture. The reconfigurable computing architecture is a data flow computing architecture without an instruction scheduling, which may implement a complete data-driven computing and a high computing energy efficiency while maintaining a very good flexibility. On the one hand, compared with a shared storage computing architecture of an NV general purpose graphics processing unit (GPGPU), a data flow computing mode of the reconfigurable computing architecture may significantly reduce an access of an external memory, thereby reducing a memory access bandwidth dependence and making a memory access bottleneck less likely to occur. For example, for a general matrix multiplication operation commonly used in an artificial intelligence algorithm, the reconfigurable computing architecture does not require an intermediate result to be read and written back and forth in the external memory, which may save 50% of the memory access bandwidth. For the computing die, a plurality of reconfigurable computing cores may be deployed on the chip. Combined with a 3D stacked DRAM chiplet, the computing cores and DRAM memories may be vertically interconnected in an one-to-one manner, and an interconnection distance is reduced to the micron level, implementing a large memory access bandwidth of 512 GB/s, and providing up to 128 MB of close-range storage capacity for each computing core, which may directly save a large amount of on-chip static random access memory (SRAM) arrangements. A single reconfigurable computing chiplet contains 32 reconfigurable computing cores, so a single chiplet may implement an extremely high memory access bandwidth of 16 TB/s. By a vertically stacked DRAM chiplet, a near-memory computing may be implemented, effectively breaking through a “storage wall” problem and significantly improving an overall performance of a packaged chip. On the other hand, a conventional GPGPU computing architecture is driven based on an instruction, and a large amount of valuable area on the computing chip is consumed in an instruction-related processing and scheduling, resulting in a computing resource constraints. Meanwhile, the single-instruction multithreading (SIMT) computing mode of the conventional GPGPU computing architecture causes a low computing resource utilization of less than 50% in typical cases for processing a sparse data set, a general computing and a typical artificial intelligence algorithm. The reconfigurable computing architecture, with its high-density computing element array and flexible programmable on-chip interconnection network, may implement a higher computing resource utilization and implement a higher actual computing power as compared to the GPGPU. In terms of the computing energy efficiency, this project uses the reconfigurable computing architecture to design a core computing die. The reconfigurable computing architecture completely eliminates an instruction overhead and drives a task execution through dynamic configuration information. An accelerated program code may be converted into a reconfigurable computing task configuration through a reconfigurable compiler. The configuration information drives an entire array to operate in a manner similar to an “application-specific integrated circuit (ASIC)”, and the computing energy efficiency is very high. The reconfigurable computing architecture may fully exploit and release various parallel capabilities contained in a program itself, such as an instruction-level parallelism (implemented through a meta-pipeline), a data-level parallelism (implemented through a single instruction multiple data (SIMD)) and a task-level parallelism (a coarse-grained pipeline, and a virtualization), which may implement a very high computational parallelism. Under the same process area, a computing performance of the reconfigurable computing architecture is twice or more and the computing energy efficiency of the reconfigurable computing architecture is ten times or higher as compared to that of an NVIDIA GPU.

In addition, FIG. 3 is a schematic diagram of a reconfigurable 3D chip according to embodiments of the second aspect of the present disclosure. Referring to FIG. 3, the reconfigurable 3D chip includes:
a reconfigurable computing chiplet and a memory chiplet disposed on a top layer of the reconfigurable computing chiplet.

The memory chiplet includes a plurality of memory elements, each reconfigurable computing element of the reconfigurable computing chiplet is configured with an independent memory element, and the reconfigurable computing element and its corresponding memory element are connected in a tight coupling manner.

In some embodiments, a data flow computing mode is adopted between a plurality of reconfigurable computing elements to implement a data transfer.

In some embodiments, the memory chiplet is a one-layer or multi-layer stacked memory.

In some embodiments, the memory element is one or more logical storage blocks.

In some embodiments, the reconfigurable computing elements inside the reconfigurable computing chiplet form a two-dimensional array.

In some embodiments, the memory chiplet at a top layer is directly stacked with the reconfigurable computing chiplet at a bottom layer, and a signal connection is implemented via a through-silicon-via technology or a hybrid bonding technology.

Specifically, embodiments of the present disclosure provide the reconfigurable 3D chip obtained by three-dimensionally integrating a DRAM chiplet and the reconfigurable computing chiplet. A logic diagram of an integration of the reconfigurable computing chiplet and a DRAM is shown in FIG. 3. PE reconfigurable computing elements in the figure are main computing modules that provide a computing power. Memories in the figure correspond to DRAM memories in a 3D integration. A reconfigurable chip architecture shown in FIG. 1 has following differences from a traditional CPU/GPU. Firstly, the traditional CPU/GPU is a shared storage computing architecture, and all computing elements operate in a unified memory space and require a large memory access bandwidth. However, the reconfigurable computing chiplet is a distributed memory computing architecture, each PE is equipped with an independent storage space, and each computing element PE and its corresponding memory are connected in a tight coupling manner, so that a memory access latency will be lower. Secondly, the traditional CPU/GPU uses an instruction-driven computing mode, a data interaction between the computing elements is performed through a global memory, and a computing performance is easily limited by a memory bandwidth and a latency. The reconfigurable computing architecture adopted in embodiments of the present disclosure is a data flow computing mode, which supports a direct data transfer between the computing elements, each PE completes its own computing tasks in its own independent storage space, and processed data are directly transferred from a local PE to other PEs, thereby implementing a data flow computing.

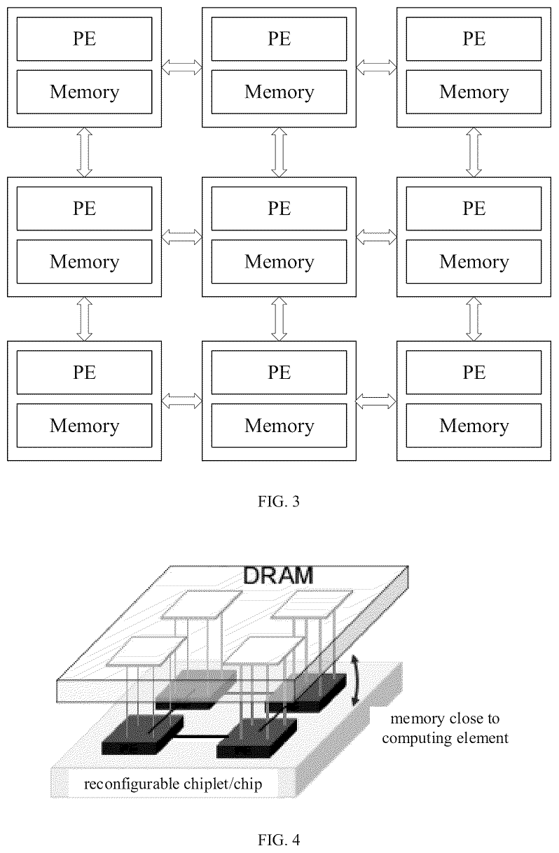

Embodiments of the present disclosure provide a method for integrating a DRAM chiplet and a reconfigurable computing chiplet into a complete chip through a three-dimensionally stacked manner. Its basic structure is shown in FIG. 4. A DRAM chiplet is at a top layer, which may be a whole chiplet or may be a plurality of chiplets. The DRAM chiplets themself may be in one layer, or may be in a plurality of layers of a stacked DRAM. The reconfigurable computing chiplet is at a bottom layer, and its interior is a two-dimensional array composed of basic computing elements PE. The DRAM chiplet at the top layer is directly stacked with the reconfigurable computing chiplet at the bottom layer, and a signal interconnection between them is implemented via a through-silicon-via (TSV) technology. One PE of the reconfigurable computing chiplet may directly correspond to a partial or complete DRAM physical/logical storage block at the top layer, or may correspond to a plurality of DRAM logical storage blocks.

Therefore, the present disclosure has following beneficial effects.

(1) The three-dimensional integration of the DRAM chiplet and the reconfigurable chiplet reduces a physical distance between a memory and a computing element to a micron level, which greatly increases a memory access bandwidth and reduces a memory access latency, significantly improving an overall performance of an integrated chip.

(2) A single-core storage capacity is significantly increased. Since the DRAM itself has a characteristic of a high storage density, and the DRAM chiplets may be stacked in a plurality of layers, a single PE may have a larger storage capacity through a vertical stacking and three-dimensional integration method.

(3) The reconfigurable computing chiplet has a stronger computing power. Since the three-dimensionally stacked integration of the DRAM memory and the reconfigurable computing chiplet may provide a stronger memory access performance for the reconfigurable computing chiplet, a memory space on a reconfigurable chip may be greatly reduced, freeing up more silicon area for computing resources, thus enabling the reconfigurable computing chiplet to implement the stronger computing power.

(4) An overall power consumption of the chip is reduced. The three-dimensional integration of the DRAM chiplet and the reconfigurable chiplet greatly reduces a connection distance between the computing element and the storage element, and a load resistance and capacitance on a connection line is also greatly reduced. Therefore, a power consumption of the memory access is significantly reduced, which effectively reduces a power consumption of an entire chip.

The basic principles of the present disclosure have been described above in conjunction with specific embodiments. However, it should be pointed out that the merits, advantages, effects, etc. mentioned in the present disclosure are only examples, and are not limiting. These merits, advantages, effects, etc. cannot be considered to be necessarily possessed by each embodiment of the present disclosure. In addition, the specific details disclosed above are only for a purpose of illustration and to facilitate understanding, and are not limiting. The above details do not limit the present disclosure to a fact that the present disclosure must be implemented using the above specific details.

Each embodiment in this specification is described in a progressive manner, and each embodiment focuses on its differences from other embodiments. For the same or similar parts between various embodiments, reference can be made to each other. For the system embodiments, since they basically correspond to the method embodiments, the description is relatively simple. For relevant details, reference may be made to the partial description of the method embodiments.

The block diagrams of components, systems, devices and lineages involved in the present disclosure are only illustrative examples and are not intended to require or imply that they must be connected, arranged, or configured in the manner shown in the block diagrams. As those skilled in the art will recognize, these components, systems, devices and lineages may be connected, arranged, and configured in any manner. Words such as “comprising/including”, “containing”, “having”, etc. are open-ended terms that mean “including, but not limited to”, and may be used interchangeably therewith. As used herein, the words “or” and “and” refer to the words “and/or” and are used interchangeably therewith unless the context clearly dictates otherwise. As used herein, the word “for example/such as” refers to the phrase “for example/such as, but not limited to”, and may be used interchangeably therewith.

The methods and systems of the present disclosure may be implemented in many ways. For example, the method and system of the present disclosure can be implemented through a software, a hardware, a firmware, or any combination of a software, a hardware, and a firmware. The above order for the steps of the methods is only for illustration, and the steps of the methods of the present disclosure are not limited to the order specifically described above unless otherwise specifically stated. Furthermore, in some embodiments, the present disclosure may also be implemented as programs recorded in the recording media, and these programs include machine-readable instructions for implementing the methods according to the present disclosure. Thus, the present disclosure also covers recording media storing a program for performing the methods according to the present disclosure.

It should also be noted that in the system, device and method of the present disclosure, each component or each step may be decomposed and/or recombined. These decompositions and/or recombinations should be regarded as equivalent solutions of the present disclosure. The above description of the disclosed aspects is provided to enable any person skilled in the art to make or use the present disclosure. Various modifications to these aspects will be readily apparent to those skilled in the art, and the generic principles defined herein may be applied to other aspects without departing from the scope of the present disclosure. Thus, the present disclosure is not intended to be limited to the aspects shown herein, but is to be in the widest scope consistent with the principles and novel features disclosed herein.

The foregoing description has been presented for a purposes of illustration and description. Furthermore, this description is not intended to limit embodiments of the present disclosure to the form disclosed herein. Although various example aspects and embodiments have been discussed above, those skilled in the art will recognize certain variations, modifications, changes, additions and sub-combinations thereof.

1. An integration method of a reconfigurable three-dimensional (3D) chip, comprising:
designing an architecture of the reconfigurable 3D chip;
performing a semiconductor manufacturing on a reconfigurable computing logic chip of the reconfigurable 3D chip to obtain an uncut reconfigurable logic wafer;
bonding the reconfigurable logic wafer and a memory wafer together in a face-to-face manner using a hybrid technology and connecting a signal input/output (IO) of the reconfigurable logic wafer and a signal IO of the memory wafer together according to the architecture of the reconfigurable 3D chip;
cutting a bonded and stacked chip to obtain an independent stacked die; and
packaging the stacked die to obtain the reconfigurable 3D chip.

2. The method according to claim 1, further comprising:
performing a development and a verification of a register transfer level (RTL) code of the reconfigurable 3D chip according to the architecture of the reconfigurable 3D chip to determine a chip RTL code.

3. The method according to claim 1, wherein performing the semiconductor manufacturing on the reconfigurable computing logic chip of the reconfigurable 3D chip to obtain the uncut reconfigurable logic wafer comprises:
performing a logical synthesis of the reconfigurable 3D chip according to the architecture of the reconfigurable 3D chip to obtain a gate-level netlist of the reconfigurable 3D chip;
performing a layout and a routing on the reconfigurable computing logic chip of the reconfigurable 3D chip according to the gate-level netlist to determine a graphic data system (GDS) file of the reconfigurable computing logic chip; and
obtaining the uncut reconfigurable logic wafer through the semiconductor manufacturing of a GDS of the reconfigurable computing logic chip according to the GDS file.

4. The method according to claim 1, wherein bonding the reconfigurable logic wafer and the memory wafer together in the face-to-face manner using the hybrid technology and connecting the signal IO of the reconfigurable logic wafer and the signal IO of the memory wafer together according to the architecture of the reconfigurable 3D chip comprise:
determining a hybrid bonding scheme of the reconfigurable computing logic chip according to a hybrid bonding rule of the architecture of the reconfigurable 3D chip; and
bonding the reconfigurable logic wafer and the memory wafer together in the face-to-face manner using the hybrid technology and connecting the signal IO of the reconfigurable logic wafer and the signal IO of the memory wafer together according to the hybrid bonding scheme.

5. A reconfigurable 3D chip obtained by an integration method of the reconfigurable 3D chip,
the integration method of the reconfigurable 3D chip, comprising:
designing an architecture of the reconfigurable 3D chip;
performing a semiconductor manufacturing on a reconfigurable computing logic chip of the reconfigurable 3D chip to obtain an uncut reconfigurable logic wafer;
bonding the reconfigurable logic wafer and a memory wafer together in a face-to-face manner using a hybrid technology and connecting a signal input/output (IO) of the reconfigurable logic wafer and a signal IO of the memory wafer together according to the architecture of the reconfigurable 3D chip;
cutting a bonded and stacked chip to obtain an independent stacked die; and
packaging the stacked die to obtain the reconfigurable 3D chip;
the reconfigurable 3D chip comprising: a reconfigurable computing chiplet and a memory chiplet disposed on a top layer of the reconfigurable computing chiplet, wherein the memory chiplet comprises a plurality of memory elements, each reconfigurable computing element of the reconfigurable computing chiplet is configured with an independent memory element, and the reconfigurable computing element and its corresponding memory element are connected in a tight coupling manner.

6. The reconfigurable 3D chip according to claim 5, wherein a data flow computing mode is adopted between a plurality of reconfigurable computing elements to implement a data transfer.

7. The reconfigurable 3D chip according to claim 5 or 6, wherein the memory chiplet is a one-layer or multi-layer stacked memory.

8. The reconfigurable 3D chip according to claim 5, wherein the memory element is one or more logical storage blocks.

9. The reconfigurable 3D chip according to claim 5, wherein the reconfigurable computing elements inside the reconfigurable computing chiplet form a two-dimensional array.

10. The reconfigurable 3D chip according to claim 5, wherein the memory chiplet at a top layer is directly stacked with the reconfigurable computing chiplet at a bottom layer, and a signal connection is implemented via a through-silicon-via technology or a hybrid bonding technology.

11. The reconfigurable 3D chip according to claim 5, further comprising:
performing a development and a verification of a register transfer level (RTL) code of the reconfigurable 3D chip according to the architecture of the reconfigurable 3D chip to determine a chip RTL code.

12. The reconfigurable 3D chip according to claim 5, wherein performing the semiconductor manufacturing on the reconfigurable computing logic chip of the reconfigurable 3D chip to obtain the uncut reconfigurable logic wafer comprises:
performing a logical synthesis of the reconfigurable 3D chip according to the architecture of the reconfigurable 3D chip to obtain a gate-level netlist of the reconfigurable 3D chip;
performing a layout and a routing on the reconfigurable computing logic chip of the reconfigurable 3D chip according to the gate-level netlist to determine a graphic data system (GDS) file of the reconfigurable computing logic chip; and
obtaining the uncut reconfigurable logic wafer through the semiconductor manufacturing of a GDS of the reconfigurable computing logic chip according to the GDS file.

13. The reconfigurable 3D chip according to claim 5, wherein bonding the reconfigurable logic wafer and the memory wafer together in the face-to-face manner using the hybrid technology and connecting the signal IO of the reconfigurable logic wafer and the signal IO of the memory wafer together according to the architecture of the reconfigurable 3D chip comprise:
determining a hybrid bonding scheme of the reconfigurable computing logic chip according to a hybrid bonding rule of the architecture of the reconfigurable 3D chip; and
bonding the reconfigurable logic wafer and the memory wafer together in the face-to-face manner using the hybrid technology and connecting the signal IO of the reconfigurable logic wafer and the signal IO of the memory wafer together according to the hybrid bonding scheme.

14. A method for integrating a dynamic random access memory (DRAM) chiplet and a reconfigurable computing chiplet into a complete chip, provided through a three-dimensionally stacked manner.

15. The method according to claim 14, wherein a dynamic random access memory (DRAM) chiplet is at a top layer, which is a whole chiplet or a plurality of chiplets.

16. The method according to claim 15, wherein the DRAM chiplets themself are in one layer, or are in a plurality of layers of a stacked DRAM.

17. The method according to claim 15, wherein the reconfigurable computing chiplet is at a bottom layer, and its interior is a two-dimensional array composed of basic computing elements PE.

18. The method according to claim 15, wherein the DRAM chiplet at the top layer is directly stacked with a reconfigurable computing chiplet at a bottom layer, and a signal interconnection between them is implemented via a through-silicon-via (TSV) technology.

19. The method according to claim 18, wherein one PE of the reconfigurable computing chiplet directly corresponds to a partial or complete DRAM physical/logical storage block at the top layer, or corresponds to a plurality of DRAM logical storage blocks.
